(19) United States
(12) Patent Application Publication
(10) Pub. No.: US 2025/0022999 A1
(43) Pub. Date: Jan. 16, 2025

(54) DISPLAY DEVICE AND MANUFACTURING METHOD THEREOF

(71) Applicant: Samsung Display Co., LTD., Yongin-si (KR)

(72) Inventor: Dong Jin PARK, Yongin-si (KR)

(73) Assignee: Samsung Display Co., LTD., Yongin-si (KR)

(21) Appl. No.: 18/629,250

(22) Filed: Apr. 8, 2024

(30) Foreign Application Priority Data
Jul. 12, 2023 (KR) 10-2023-0090714

(51) Int. Cl. H01L 33/62; H01L 25/075

(52) U.S. Cl. CPC H01L 33/62; H01L 25/0753; H01L 2933/0066

(57) ABSTRACT

A method of manufacturing a display device includes forming a pad part on an upper surface of a substrate, forming a lower electrode on a lower surface of the substrate, connecting the lower electrode and a flexible circuit board to each other, disposing, on a side surface of the substrate, a conductive material for electrically connecting the pad part and the lower electrode to each other, and forming a side surface connection line by an electromagnetic wave output device irradiating an electromagnetic wave having a wavelength onto the conductive material on the side surface of the substrate. In the display device and the manufacturing method thereof in accordance with the disclosure, a time necessary to form a side surface connection line is shortened.

### CROSS-REFERENCE TO RELATED APPLICATION(S)

This application claims priority to and benefits of Korean patent application No. 10-2023-0090714 under 35 U.S.C. § 119 (a), filed on Jul. 12, 2023, in the Korean Intellectual Property Office (KIPO), the entire contents of which are incorporated herein by reference.

### BACKGROUND

### 1. Technical Field

The disclosure generally relates to a display device and a manufacturing method thereof.

### 2. Description of the Related Art

With the development of information technologies, the importance of a display device which is a connection medium between a user and information increases. Accordingly, display devices such as a liquid crystal display device and an organic light emitting display device are increasingly used.

In order to widen the area of a display area in which an image is displayed in a display device, circuit components required to supply various signals and various voltages may be disposed on a back surface of a substrate in the display device.

In order to supply signals and voltages to circuit elements located on a front surface of the display device, a conductive material for allowing the circuit elements to be electrically conductive may be located at a side surface of the substrate. A side surface connection line may be formed by hardening the conductive material.

### SUMMARY

Embodiments provide a display device and a manufacturing method thereof, which can shorten a time required to form a side surface connection line.

In accordance with an embodiment of the disclosure, a method of manufacturing a display device may include forming a pad part on an upper surface of a substrate, forming a lower electrode on a lower surface of the substrate, connecting the lower electrode and a flexible circuit board to each other, disposing, on a side surface of the substrate, a conductive material for electrically connecting the pad part and the lower electrode to each other, and forming a side surface connection line by an electromagnetic wave output device irradiating an electromagnetic wave having a wavelength onto the conductive material on the side surface of the substrate.

The wavelength of the electromagnetic wave may be in a range of about 1 mm to about 1 m.

The side surface connection line may include one of silver, molybdenum, aluminum, chromium, gold, titanium, nickel, neodymium, and copper, and an alloy thereof.

The upper surface and the lower surface may be arranged parallel to a plane defined by a first direction and a second direction, which are perpendicular to each other. The side surface connection line may extend in a third direction perpendicular to the first direction and the second direction, and electrically connect the pad part and the lower electrode to each other.

An induced current may be formed in the third direction by the electromagnetic wave in the side surface connection line.

The electromagnetic wave output device may include at least one electromagnetic wave output unit. The at least one electromagnetic wave output unit may move in the first direction or the second direction.

The at least one electromagnetic wave output unit may irradiate the electromagnetic wave with a uniform intensity while moving in the first direction or the second direction.

The at least one electromagnetic wave output unit may move in the first direction along a side of the substrate and move in the second direction along another side of the substrate.

A velocity at which the at least one electromagnetic wave output unit moves in the first direction and a velocity at which the at least one electromagnetic wave output unit moves in the second direction may be same.

The electromagnetic wave output device may include a first electromagnetic wave output unit moving in the first direction along a side of the substrate, and a second electromagnetic wave output unit moving in the second direction along another side of the substrate.

Moving velocities of the first electromagnetic wave output unit and the second electromagnetic wave output unit may be same.

A moving velocity of the at least one electromagnetic wave output unit may be set according to a thickness of the side surface connection line.

The moving velocity of the at least one electromagnetic wave output unit may be set in inverse proportion to the thickness of the side surface connection line.

The side surface connection line may include a plane heating pattern.

The conductive material may be printed using a stamp method.

The electromagnetic wave output device may include a magnetron that generates a microwave.

In accordance with an embodiment of the disclosure, a display device may include a pad part disposed on an upper surface of a substrate, a lower electrode disposed on a lower surface of the substrate, the lower electrode being electrically connected to a flexible film, and a side surface connection line that electrically connects the pad part and the lower electrode to each other, the side surface connection line including a conductive material. The side surface connection line may be formed by being heated by an electromagnetic wave having a wavelength.

The display device may further include a pixel circuit layer disposed in a display area of the substrate, and a display element layer disposed on the pixel circuit layer. The pad part may be electrically connected to the pixel circuit layer or the display element layer.

The display element layer may include a micro light emitting diode.

The side surface connection line may include a plane heating pattern.

### BRIEF DESCRIPTION OF THE DRAWINGS

Embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey the scope of the example embodiments to those skilled in the art.

In the drawing figures, dimensions may be exaggerated for clarity of illustration. It will be understood that when an element is referred to as being “between” two elements, it can be the only element between the two elements, or one or more intervening elements may also be present. Like reference numerals refer to like elements throughout.

FIG. 1 is a view schematically illustrating a display device in accordance with embodiments of the disclosure.

FIG. 2 is a view schematically illustrating an embodiment of a pixel included in the display device shown in FIG. 1.

FIG. 3 is a view schematically illustrating another embodiment of the pixel included in the display device shown in FIG. 1.

FIG. 4 is a view schematically illustrating a tiled display device in accordance with embodiments of the disclosure.

FIG. 5 is a perspective view schematically illustrating a display device in accordance with embodiments of the disclosure.

FIG. 6 is a view schematically illustrating an embodiment of a portion of a back surface of the display device shown in FIG. 5.

FIG. 7 is a schematic cross-sectional view illustrating an embodiment of the display device shown in FIG. 5.

FIG. 8 schematically illustrates an embodiment of a process of forming a side surface connection line of the display device shown in FIG. 5.

FIGS. 9A and 9B schematically illustrate an embodiment in which an electromagnetic wave output device shown in FIG. 8 includes one electromagnetic wave output unit.

FIGS. 10A and 10B schematically illustrate an embodiment in which the electromagnetic wave output device shown in FIG. 8 includes multiple electromagnetic wave output units.

FIG. 11 is a view schematically illustrating the electromagnetic wave output device used in the process shown in FIG. 8 and the side surface connection line of the display device shown in FIG. 5.

FIG. 12 is a view schematically illustrating a pattern viewed in the side surface connection line formed through the process shown in FIG. 8.

### DETAILED DESCRIPTION OF THE EMBODIMENTS

Hereinafter, embodiments are described in detail with reference to the accompanying drawings so that those skilled in the art may readily practice the disclosure. The disclosure may be implemented in various different forms and is not limited to the embodiments described in the specification.

A part irrelevant to the description will be omitted to clearly describe the disclosure, and the same or similar constituent elements will be designated by the same reference numerals throughout the specification. Therefore, the same reference numerals may be used in different drawings to identify the same or similar elements.

In addition, the size and thickness of each component illustrated in the drawings are arbitrarily shown for better understanding and ease of description, but the disclosure is not limited thereto. Thicknesses of several portions and regions are exaggerated for clear expressions.

In description, the expression “equal” may mean “substantially equal.” That is, this may mean equality to a degree to which those skilled in the art can understand the equality. Other expressions may be expressions in which “substantially’ is omitted.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Also, when an element is referred to as being “in contact” or “contacted” or the like to another element, the element may be in “electrical contact” or in “physical contact” with another element; or in “indirect contact” or in “direct contact” with another element.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the exemplary term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Unless otherwise defined or implied herein, all terms (including technical and scientific terms) used have the same meaning as commonly understood by those skilled in the art to which this disclosure pertains. It will be further understood that terms, such as those defined in commonly used dictionaries, should be interpreted as having a meaning that is consistent with their meaning in the context of the relevant art and should not be interpreted in an ideal or excessively formal sense unless clearly defined in the specification.

Hereinafter, embodiments of the disclosure will be described in detail with reference to the accompanying drawings.

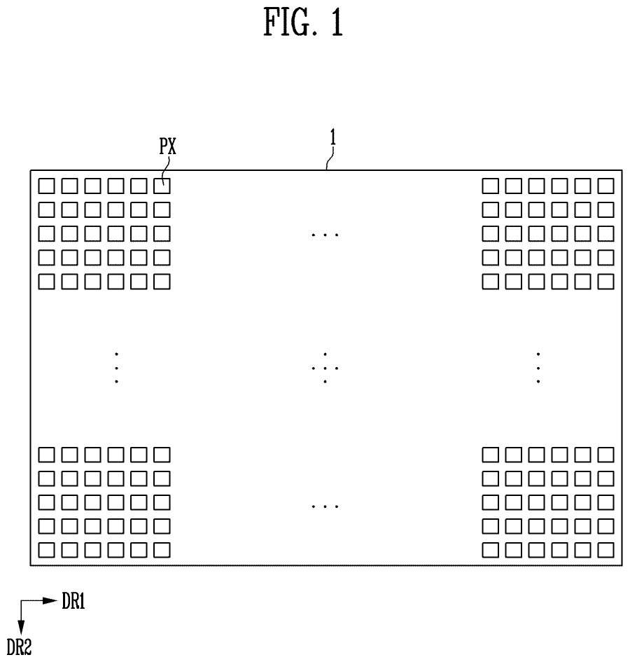

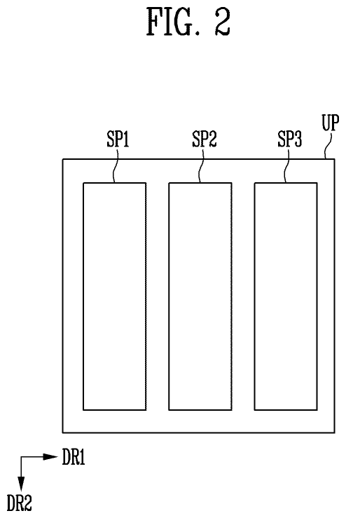

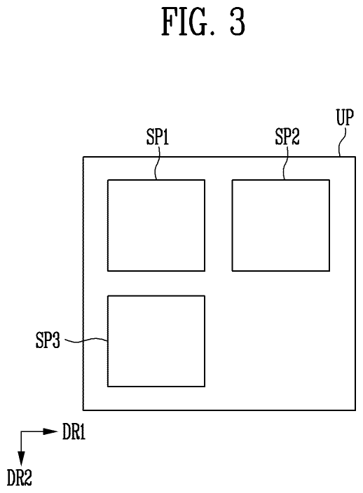

FIG. 1 is a view schematically illustrating a display device 1 in accordance with embodiments of the disclosure. FIG. 2 is a view schematically illustrating an embodiment of a pixel included in the display device 1 shown in FIG. 1. FIG. 3 is a view schematically illustrating another embodiment of the pixel included in the display device 1 shown in FIG. 1.

Referring to FIGS. 1, 2, and 3, the display device 1 may include pixels PX.

The display device 1 may be a device which displays a moving image or a still image, and may be used as a display screen of not only portable electronic devices such as a mobile phone, a smart phone, a tablet personal computer (PC), a mobile communication terminal, an electronic notebook, an electronic book, a portable multimedia player (PMP), a navigation system, and an ultra-mobile PC, but also various products such as a television, a notebook computer, a monitor, an advertisement board, and Internet of things (IOT).

The display device 1 (or a display panel) may be formed in a rectangular plane shape having long sides in a first direction DR1 and short sides in a second direction DR2 intersecting the first direction DR1. A corner at which the long side in the first direction DR1 and the short side in the second direction DR2 meet each other may be formed round to have a curvature or be formed at a right angle. The planar shape of the display device 1 is not limited to a quadrangular shape, and the display device 1 may be formed in another polygonal shape, a circular shape, or an elliptical shape. The display device 1 may be a flat panel display device, but the disclosure is not limited thereto. For example, the display device 1 may include a curved part which is formed at a left/right end and has a constant curvature or a changing curvature. The display device 1 may be formed flexible enough to be wrappable, curvable, bendable, foldable or rollable.

Each of the pixels PX may be a unit pixel UP as shown in FIGS. 2 and 3. Each unit pixel UP may include first, second, and third pixels SP1, SP2, and SP3. In FIGS. 2 and 3, it is illustrated that the unit pixel UP includes three pixels SP1, SP2, and SP3. However, the embodiments of the disclosure are not limited thereto.

The first pixel SP1, the second pixel SP2, and the third pixel SP3 may emit light of different colors. Each of the first pixel SP1, the second pixel SP2, and the third pixel SP3 may have a rectangular, square or rhombic planar shape in a plan view. For example, each of the first pixel SP1, the second pixel SP2, and the third pixel SP3 may have a rectangular shape having short sides in the first direction DR1 and long sides in the second direction DR2 in a plan view as shown in FIG. 2. In another embodiment, each of the first pixel SP1, the second pixel SP2, and the third pixel SP3 may have a square or rhombic planar shape including sides in a plan view as shown in FIG. 3.

In an embodiment, as shown in FIG. 2, the first pixel SP1, the second pixel SP2, and the third pixel SP3 may be arranged in the first direction DR1.

In another embodiment, one of the second pixel SP2 and the third pixel SP3 and the first pixel SP1 may be arranged in the first direction DR1, and another one of the second pixel SP2 and the third pixel SP3 and the first pixel SP1 may be arranged in the second direction DR2 . For example, as shown in FIG. 3, the second pixel SP2 may be arranged in the first direction DR1 with respect to the first pixel SP1, and the third pixel SP3 may be arranged in the second direction DR2 with respect to the first pixel SP1.

The first pixel SP1 may emit first light, the second pixel SP2 may emit second light, and the third pixel SP3 may emit third light. The first light may be light in a red wavelength band, the second light may be light in a green wavelength band, and the third light may be light in a blue wavelength band. The red wavelength band may be a wavelength band in a range of about 600 nm (nanometer) to about 750 nm, the green wavelength band may be a wavelength band in a range of about 480 nm to about 560 nm, and the blue wavelength band may be a wavelength band in a range of about 370 nm to about 460 nm. However, the embodiments of the disclosure are not limited thereto.

The display device 1 may be implemented as, for example, a light-receiving and light emitting display device (e.g., a liquid crystal display device) including a light source (e.g., a backlight unit). The display device 1 may be implemented as, for example, a self-luminous display device including a light emitting element. Hereinafter, although an embodiment that the display device 1 is implemented as a self-luminous display device including a light emitting element is described, the embodiments of the disclosure are not limited thereto.

Each of the first pixel SP1, the second pixel SP2, and the third pixel SP3 may include a light emitting element. The light emitting element may include, for example, an organic light emitting element including an organic light emitting layer. The light emitting element may include, for example, an inorganic light emitting element having an inorganic semiconductor. For example, the inorganic light emitting element may be a flip-chip type micro light emitting diode (LED), but the embodiments of the disclosure are not limited thereto. Hereinafter, an embodiment that the light emitting element is implemented as an inorganic light emitting element having an inorganic semiconductor is described, but the embodiments of the disclosure are not limited thereto.

As shown in FIGS. 2 and 3, an area of the first pixel SP1, an area of the second pixel SP2, and an area of the third pixel SP3 in a plan view may be substantially the same. However, the embodiments of the disclosure are not limited thereto. The area of a pixel may be an area of a light emitting element (or light source) included in the corresponding pixel or an area of an emission area of the light emitting element in a plan view.

At least one of the area of the first pixel SP1, the area of the second pixel SP2, and the area of the third pixel SP3 may be different from another one of the area of the first pixel SP1, the area of the second pixel SP2, and the area of the third pixel SP3. In another embodiment, two of the area of the first pixel SP1, the area of the second pixel SP2, and the area of the third pixel SP3 may be substantially the same, and another one of the area of the first pixel SP1, the area of the second pixel SP2, and the area of the third pixel SP3 may be different from the two of the area of the first pixel SP1, the area of the second pixel SP2, and the area of the third pixel SP3. In another embodiment, the area of the first pixel SP1, the area of the second pixel SP2, and the area of the third pixel SP3 may be different from one another.

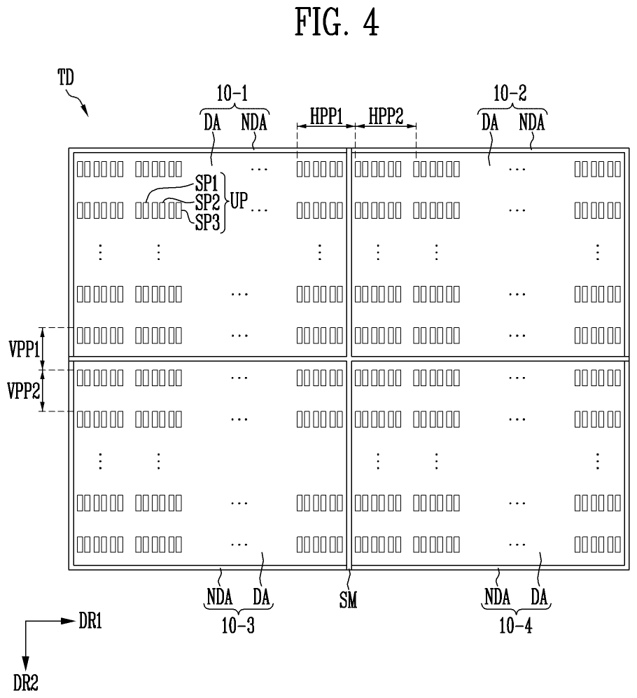

FIG. 4 is a view schematically illustrating a tiled display device TD in accordance with embodiments of the disclosure.

Referring to FIG. 4, the tiled display device TD may include multiple display devices 10-1, 10-2, 10-3, and 10-4. For example, the display devices 10-1, 10-2, 10-3, and 10-4 may be arranged in a lattice form, but the embodiments of the disclosure are not limited thereto.

The shape of the tiled display device TD may vary according to a form in which the display devices 10-1, 10-2, 10-3, and 10-4 are arranged. Referring to FIG. 4, the display devices 10-1, 10-2, 10-3, and 10-4 are arranged in the first direction DR1 (or an X-axis direction) and/or the second direction DR2 (or a Y-axis direction) to be connected to each other, and therefore, the tiled display device TD may have a specific shape.

The display devices 10-1, 10-2, 10-3, and 10-4 may have a same size, but the embodiments of the disclosure are not limited thereto. For example, at least some of the display devices 10-1, 10-2, 10-3, and 10-4 may have a size different from a size of the others of the display devices 10-1, 10-2, 10-3, and 10-4.

The tiled display device TD may include multiple display devices. Referring to FIG. 4, the tiled display device TD may include a first display device 10-1, a second display device 10-2, a third display device 10-3, and a fourth display device 10-4. The number of display devices included in the tiled display device TD and the coupling relationship between the display devices are not limited to the embodiments shown in FIG. 4. Hereinafter, for convenience of description, an embodiment that the tiled display device TD includes four display devices 10-1, 10-2, 10-3, and 10-4 is described. However, the embodiments of the disclosure are not limited thereto.

The first to fourth display devices 10-1 to 10-4 may be fixed to a mounting frame to implement a large-screen image.

Each of the first to fourth display devices 10-1 to 10-4 may have a rectangular shape including long sides and short sides in a plan view. The first to fourth display devices 10-1 to 10-4 may be disposed while long sides or short sides thereof are connected to each other.

Some of the display devices may be disposed at an edge of the tiled display device TD, to constitute a side of the tiled display device TD. For example, some of the first to fourth display devices 10-1 to 10-4 may be disposed at an edge of the tiled display device TD, to form a side of the tiled display device TD.

Some of the display devices may be disposed at a corner of the tiled display device TD. For example, some of the first to fourth display devices 10-1 to 10-4 may be disposed at a corner of the tiled display device TD, and form two adjacent sides of the tiled display device TD.

Some of the display devices may be disposed inside the tiled display device TD. Although not shown in the drawing, some of the display devices may be disposed inside the tiled display device TD and surrounded by other display devices.

Each of the display devices may include a display area DA and a non-display area NDA. For example, each of the first to fourth display devices 10-1, 10-2, 10-3, and 10-4 may include a display are DA and a non-display area NDA. The display area DA may include unit pixels UP, and display an image. In some embodiments, the unit pixel UP may include first, second, and third pixels SP1, SP2, and SP3. In some embodiments, each of the first, second, and third pixels SP1, SP2, and SP3 may include a micro LED. However, the disclosure is not limited thereto, and in another embodiment, each of the first, second, and third pixels SP1, SP2, and SP3 may include an organic light emitting diode including an organic light emitting layer, a quantum dot LED including a quantum dot light emitting layer, or an inorganic LED including an inorganic semiconductor. Hereinafter, an embodiment that each of the first, second, and third pixels SP1, SP2, and SP3 includes a micro LED is described.

The non-display area NDA may be disposed at the periphery of the display area DA, and surround at least a portion of the display area DA. The non-display area NDA may not display the image.

Referring to FIG. 4, each of the first to fourth display devices 10-1 to 10-4 may include first, second, and third pixels SP1, SP2, and SP3 arranged along multiple rows and multiple columns in the display area DA. Each of the first, second, and third pixels SP1, SP2, and SP3 may include an emission area or an opening area, which is defined by a pixel defining layer or a bank, and emit light having a peak wavelength (a predetermined or selectable peak wavelength) through the emission area or the opening area. The emission area may be an area in which light generated in a light emitting element of each of the first, second, and third pixels SP1, SP2, and SP3 is emitted to the outside of each of the first to fourth display devices 10-1 to 10-4.

The first, second, and third pixels SP1, SP2, and SP3 may be sequentially and repeatedly arranged in the first direction DR1 of the display area DA.

The tiled display device TD may have a planar shape, but the embodiments of the disclosure are not limited thereto. The tiled display device TD may have a stereoscopic shape, thereby providing a stereoscopic effect to a user. For example, the tiled display device TD may have a stereoscopic shape, and at least some of the display devices 10-1, 10-2, 10-3, and 10-4 may have a curved shape. In another embodiment, each of the display devices 10-1, 10-2, 10-3, and 10-4 may have a planar shape, and be connected to each other at an angle, so that the tiled display device TD has a stereoscopic shape.

The tiled display device TD may include a coupling area SM disposed between the display areas DA. The tiled display device TD may be formed by connecting the non-display areas NDA of respective adjacent display devices. The first to fourth display devices 10-1 to 10-4 may be connected to each other through a coupling member or an adhesive member, which is disposed in the coupling area SM.

A distance between the display areas DA of the respective first to fourth display devices 10-1 to 10-4 may be close enough that the coupling area SM is not recognized by the user. For example, a first horizontal pixel pitch HPP1 between pixels of the first display device 10-1 and pixels of the second display device 10-2 may be substantially equal to a second horizontal pixel pitch HPP2 between the pixels of the second display device 10-2. A first vertical pixel pitch VPP1 between the pixels of the first display device 10-1 and pixels of the third display device 10-3 may be substantially equal to a second vertical pixel pitch VPP2 between the pixels of the third display device 10-3. The tiled display device TD may prevent the coupling area SM between the display devices (e.g., the first to fourth display devices 10-1 to 10-4) from being recognized by the user, thereby reducing sense of disconnection between the display devices and improving concentrativeness for an image.

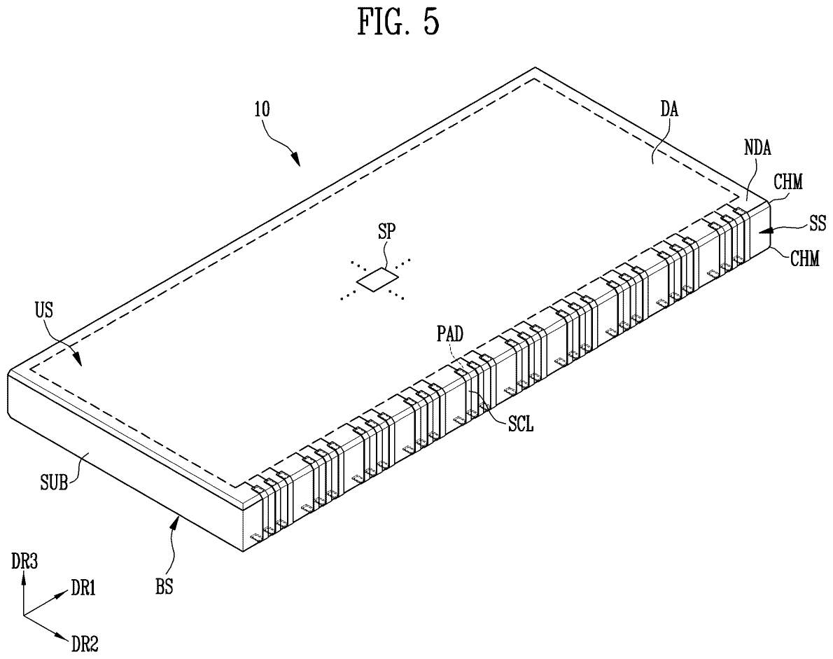

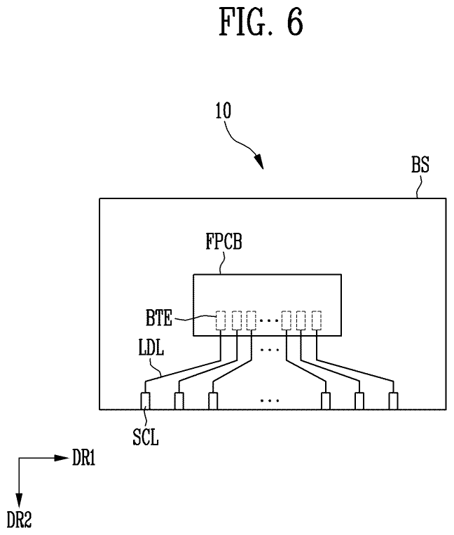

FIG. 5 is a perspective view schematically illustrating a display device 10 in accordance with embodiments of the disclosure. FIG. 6 is a view schematically illustrating an embodiment of a portion of a back surface BS of the display device 10 shown in FIG. 5.

FIG. 5 is schematically illustrated based on a configuration of a pad part PAD and a side surface connection line SCL, and the configuration of the pad part PAD and the side surface connection line SCL will be described. FIG. 6 illustrates an embodiment in which the side surface connection line SCL is connected to other components on a back surface BS of a substrate SUB. The display device 10 shown in FIG. 5 may be applied to the display device 1 shown in FIG. 1.

Referring to FIGS. 5 and 6, the display device 10 may include a substrate SUB including a display area DA and a non-display area NDA, at least one pad part PAD disposed on an upper surface US of the substrate SUB, and at least one side surface connection line SCL disposed on the upper surface US, a back surface BS, and a side surface SS between the upper surface US and the back surface BS of the substrate SUB.

The upper surface US and the back surface BS of the substrate SUB may face each other with respect to a third direction DR3.

In an embodiment, the substrate SUB may include a chamfered surface CHM formed by chamfering each of an edge between the upper surface US and the side surface SS and an edge between the back surface BS and the side surface SS. The side surface SS of the substrate SUB may have an inclination due to the chamfered surface CHM. Accordingly, disconnection of the side surface connection line SCL surrounding the upper surface US, the side surface SS, and the back surface BS of the substrate SUB may be prevented.

The pad part PAD may be arranged in the non-display area NDA of the upper surface US of the substrate SUB. In FIG. 5, it is illustrated that the pad part PAD is disposed at an edge of the upper surface US of the substrate SUB. However, the disclosure is not limited thereto, and the pad part PAD may be also disposed at other edges of the upper surface US of the substrate SUB.

In an embodiment, the pad part PAD (e.g., a pad of the pad part PAD) may be in contact with the side surface connection line SCL. The side surface connection line SCL may be connected to one of a data line, a power line, and a clock line, which are used to drive a pixel PX (see FIG. 1). For example, the power line may include power lines for supplying various power sources supplied to a gate driver and/or the pixel PX (see FIG. 1). Clock signals supplied to the gate driver may be provided to the clock lines.

The side surface connection line SCL may be connected one-to-one to the pad part PAD (e.g., the pad of the pad part PAD). The side surface connection line SCL may be physically and electrically connected to the pad part PAD. In an embodiment, the side surface connection line SCL may entirely cover an upper surface of the pad part PAD. Thus, physical and/or electrical connection between the pad part PAD and the side surface connection line SCL may be reinforced.

In an embodiment, a width of the side surface connection line SCL may be tens of um (micrometer). In an embodiment, a distance between side surface connection lines SCL adjacent to each other may be tens of μm. In an embodiment, the width of the side surface connection line SCL may be equal to or greater than the distance between the side surface connection lines SCL adjacent to each other.

Referring to FIG. 6, at least one lead line LDL, at least one back surface electrode BTE, a flexible film FPCB, and the like may be disposed on the back surface BS of the substrate SUB.

The lead line LDL may be connected (e.g., physically and/or electrically connected) between the side surface connection line SCL and the back surface electrode BTE. In an embodiment, an end of the lead line LDL may be physically connected to the side surface connection line SCL extending to the back surface BS of the substrate SUB. Another end of the lead line LDL may be physically connected to the back surface electrode BTE formed on the back surface BS of the substrate SUB.

The back surface electrode BTE may supply a voltage and/or a signal received from the flexible film FPCB to the side surface connection line SCL through the lead line LDL. In an embodiment, the back surface electrode BTE and the flexible film FPCB may be electrically connected to each other through a conductive adhesive member (e.g., an anisotropic conductive film or the like). For example, at least a portion of a first surface of the flexible film FPCB may be attached to the back surface BS of the substrate SUB through the conductive adhesive member. A second surface facing the first surface of the flexible film FPCB may be connected to a source circuit board, a driving chip, and the like.

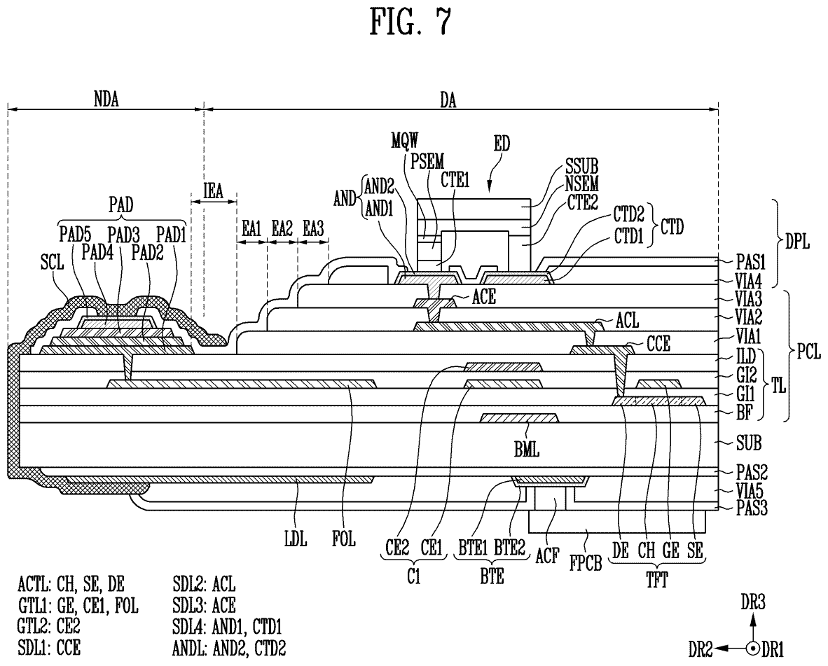

FIG. 7 is a schematic cross-sectional view illustrating an embodiment of the display device 10 shown in FIG. 5.

Referring to FIGS. 5, 6, and 7, the display device 10 may include the substrate SUB, a pixel circuit layer PCL, a display element layer DPL, and the like.

A stacked structure may be formed on each of the upper surface US and the back surface of the substrate SUB. For example, the pixel circuit layer PCL and the display element layer DPL may be disposed to be stacked on the upper surface US of the substrate SUB.

Referring to FIG. 7, the pixel circuit layer PCL may include a light blocking layer BML, a buffer layer BF, an active layer ACTL, a first gate insulating layer GI1, a first gate electrode layer GTL1, a second gate insulating layer GI2, a second gate electrode layer GTL2, an interlayer insulating layer ILD, a first source metal layer SDL1, a first via layer VIA1, a second source metal layer SDL2, a second via layer VIA2, a third source metal layer SDL3, a third via layer VIA3, and the like.

The display element layer DPL may include a fourth source metal layer SDL4, an anode layer ANDL, a fourth via layer VIA4, a first protective layer PAS1, and the like.

A second protective layer PAS2, the back surface electrode BTE, the lead line LDL, a fifth via layer VIA5, a third protective layer PAS3, the flexible film FPCB, and the like may be disposed on the back surface BS of the substrate SUB.

The side surface connection line SCL may be disposed on the upper surface US and the back surface BS of the substrate SUB via the side surface SS of the substrate SUB.

The substrate SUB may entirely support layers stacked on the upper surface US and the back surface BS of the substrate SUB. The substrate SUB may be a base substrate or a base member. The substrate SUB may be a rigid substrate including a glass material. In another embodiment, the substrate SUB may be a flexible substrate which is bendable, foldable, rollable, and the like. For example, the substrate SUB may include an insulating material such as a polymer resin including polyimide (PI), but the disclosure is not limited thereto.

The light blocking layer BML may be disposed on the substrate SUB. The light blocking layer BML may have a single layer or a multi-layer, which is made of one of molybdenum (Mo), aluminum (Al), chromium (Cr), gold (Au), titanium (Ti), nickel (Ni), neodymium (Nd), and copper (Cu), or an alloy thereof.

In an embodiment, the light blocking layer BML may be connected to an electrode (e.g., a source electrode) of a transistor TFT (e.g., a driving transistor). In an embodiment, the light blocking layer BML may overlap at least a portion of the active layer ACTL of the transistor TFT in a plan view, and block light incident onto the active layer ACTL, thereby stabilizing an operation of the transistor TFT.

The buffer layer BF may be disposed on the substrate SUB. The buffer layer BF may include an inorganic material capable of preventing infiltration of air or moisture. The buffer layer BF may include multiple inorganic layers which are alternately stacked each other. For example, the buffer layer BF may have a multi-layer in which one or more inorganic layers among a silicon nitride layer, a silicon oxynitride layer, a silicon oxide layer, a titanium oxide layer, and an aluminum oxide layer are stacked each other.

The active layer ACTL may be disposed on the buffer layer BF. The active layer ACTL may include a channel CH, a source electrode SE, and a drain electrode DE of the transistor TFT. The transistor TFT may be a transistor constituting a pixel circuit. The source electrode SE and the drain electrode DE may become conductors by heat-treating the active layer ACTL. For example, the active layer ACTL may include polycrystalline silicon, single crystalline silicon, low temperature polycrystalline silicon, amorphous silicon, an oxide semiconductor, or the like. In another embodiment, the active layer ACTL may include first and second active layers disposed in different layers. The first active layer may include polycrystalline silicon, single crystalline silicon, low temperature polycrystalline silicon, or amorphous silicon, and the second active layer may include an oxide semiconductor.

The first gate insulating layer GI1 may be disposed over the active layer ACTL. The first gate insulating layer GI1 may insulate a gate electrode GE and the channel CH of the transistor TFT from each other. The first gate insulating layer GI1 may include an inorganic layer. For example, the first gate insulating layer GI1 may include one of a silicon nitride layer, a silicon oxynitride layer, a silicon oxide layer, a titanium oxide layer, and an aluminum oxide layer.

The first gate electrode layer GTL1 may be disposed on the first gate insulating layer GI1. The first gate electrode layer GTL1 may include a fan-out line POL, the gate electrode GE of the transistor TFT, and a first capacitor electrode CE1 (e.g., a lower electrode) of a first capacitor C1. The first gate electrode layer GTL1 may have a single layer or a multi-layer, which is made of one of molybdenum (Mo), aluminum (Al), chromium (Cr), gold (Au), titanium (Ti), nickel (Ni), neodymium (Nd), and copper (Cu), or an alloy thereof.

The fan-out line FOL may be connected to the pad part PAD penetrating the interlayer insulating layer ILD and the second gate insulating layer GI2. In an embodiment, the fan-out line FOL may extend from the pad part PAD to the display area DA, to decrease the size of the non-display area NDA.

The second gate insulating layer GI2 may be disposed over the first gate electrode layer GTL1. The second gate insulating layer GI2 may insulate the first gate electrode layer GTL1 and the second gate electrode layer GTL2 from each other. The second gate insulating layer GI2 may include an inorganic layer. For example, the second gate insulating layer GI2 may include one of a silicon nitride layer, a silicon oxynitride layer, a silicon oxide layer, a titanium oxide layer, and an aluminum oxide layer.

The second gate electrode layer GTL2 may be disposed on the second gate insulating layer GI2. The second gate electrode layer GTL2 may include a second capacitor electrode CE2 (e.g., an upper electrode) of the first capacitor C1. The second gate electrode layer GTL2 may have a single layer or a multi-layer, which is made of one of molybdenum (Mo), aluminum (Al), chromium (Cr), gold (Au), titanium (Ti), nickel (Ni), neodymium (Nd), and copper (Cu), or an alloy thereof.

The interlayer insulating layer ILD may be disposed over the second gate electrode layer GTL2. The interlayer insulating layer ILD may insulate the first source metal layer SDL1 and the second gate electrode layer GTL2 from each other. The interlayer insulating layer ILD may include an inorganic layer. For example, the interlayer insulating layer ILD may include one of a silicon nitride layer, a silicon oxynitride layer, a silicon oxide layer, a titanium oxide layer, and an aluminum oxide layer.

A configuration including the transistor TFT, the buffer layer BF, the first gate insulating layer GI1, the second gate insulating layer GI2, and the interlayer insulating layer ILD may constitute a transistor layer TL. For example, an uppermost layer of the transistor layer TL may be the interlayer insulating layer ILD. The transistor layer TL may be a portion of the pixel circuit layer PCL.

The first source metal layer SDL1 may be disposed on the interlayer insulating layer ILD of the transistor layer TL. The first source metal layer SDL1 may include a connection electrode CCE.

The connection electrode CCE may be connected to an anode connection line ACL penetrating the first protective layer PAS1 and the first via layer VIA1. The connection electrode CCE may be connected to the drain electrode DE of the transistor TFT while penetrating the interlayer insulating layer ILD, the second gate insulating layer GI2, and the first gate insulating layer GI1. The connection electrode CCE may electrically connect the anode connection line ACL and the drain electrode DE to each other.

A first pad electrode PAD1 may be formed together with the first source metal layer SDL1. The first pad electrode PAD1 may be disposed on the interlayer insulating layer ILD in the non-display area NDA.

The first pad electrode PAD1 may be connected to the fan-out line FOL through a contact hole penetrating the interlayer insulating layer ILD and the second gate insulating layer GI2.

Each of the first source metal layer SDL1 and the first pad electrode PAD1 may have a single layer or a multi-layer, which is made of one of molybdenum (Mo), aluminum (Al), chromium (Cr), gold (Au), titanium (Ti), nickel (Ni), neodymium (Nd), and copper (Cu), or an alloy thereof.

The first via layer VIA1 may be disposed over the first source metal layer SDL1. The first via layer VIA1 may planarize an upper surface of the first source metal layer SDL1. The first via layer VIA1 may include an organic layer including an acrylic resin, an epoxy resin, a phenol resin, a polyamide resin, a polyimide resin, or the like.

In an embodiment, the first via layer VIA1 may be disposed in the display area DA. The first via layer VIA1 may be spaced apart from the first pad electrode PAD1. Accordingly, an interlayer insulating layer exposed area IEA may be formed between the first via layer VIA1 and the pad part PAD (e.g., the first pad electrode PAD1). The interlayer insulating exposed area IEA may be a portion at which an upper surface of the interlayer insulating layer ILD is exposed from the first via layer VIA1 between the first via layer VIA1 and the pad part PAD.

The second source metal layer SDL2 may be disposed on the first via layer VIA1. The second source metal layer SDL2 may include the anode connection line ACL. The anode connection line ACL may be connected to an anode connection electrode ACE penetrating the second via layer VIA2.

The anode connection line ACL may be connected to the connection electrode CCE while penetrating the first via layer VIA1. The anode connection line ACL may electrically connect the anode connection electrode ACE and the connection electrode CCE to each other.

A second pad electrode PAD2 may be formed together with the second source metal layer SDL2. The second pad electrode PAD2 may be disposed on (e.g., directly on) the first pad electrode PAD1. The second pad electrode PAD2 may be formed in the non-display area NDA.

Each of the second source metal layer SDL2 and the second pad electrode PAD2 may have a single layer or a multi-layer, which is made of one of molybdenum (Mo), aluminum (Al), chromium (Cr), gold (Au), titanium (Ti), nickel (Ni), neodymium (Nd), and copper (Cu), or an alloy thereof.

The second via layer VIA2 may be disposed on the first via layer VIA1 and the second source metal layer SDL2. The second via layer VIA2 may planarize an upper surface of the second source metal layer SDL2. The second via layer VIA2 may include an organic layer including an acrylic resin, an epoxy resin, a phenol resin, a polyamide resin, a polyimide resin, or the like.

In an embodiment, the second via layer VIA2 may be disposed in the display area DA. The second via layer VIA2 may be spaced apart from the pad part PAD. Also, the second via layer VIA2 and the first via layer VIA1 may form a step difference to expose a portion of an upper surface of the first via layer VIA1. The portion at which the first via layer VIA1 is exposed from the second via layer VIA2 may be a first exposed area EA1. For example, a width of the first exposed area EA1 in the second direction DR2 may be about 10 μm.

The third source metal layer SDL3 may be disposed on the second via layer VIA2. The third source metal layer SDL3 may include the anode connection electrode ACE. The anode connection electrode ACE may be connected to a first anode electrode AND1 penetrating the third via layer VIA3. The anode connection electrode ACE may be connected to the anode connection line ACL while penetrating the second protective layer PAS2 and the second via layer VIA2. The anode connection electrode ACE may be electrically connected to an anode AND and the anode connection line ACL.

A third pad electrode PAD3 may be formed together with the third source metal layer SDL3. The third pad electrode PAD3 may be disposed on (e.g., directly on) the second pad electrode PAD2. The third pad electrode PAD3 may be formed in the non-display area NDA.

Each of the third source metal layer SDL3 and the third pad electrode PAD3 may have a single layer or a multi-layer, which is made of one of molybdenum (Mo), aluminum (Al), chromium (Cr), gold (Au), titanium (Ti), nickel (Ni), neodymium (Nd), and copper (Cu), or an alloy thereof.

The third via layer VIA3 may be disposed on the second via layer VIA2 and the third source metal layer SDL3. The third via layer VIA3 may planarize an upper surface of the third source metal layer SDL3. The third via layer VIA3 may include an organic layer including an acrylic resin, an epoxy resin, a phenol resin, a polyamide resin, a polyimide resin, or the like.

In an embodiment, the third via layer VIA3 may be disposed in the display area DA. The third via layer VIA3 may be spaced apart from the pad part PAD. Also, the third via layer VIA3 and the second via layer VIA2 may form a step difference to expose a portion of an upper surface of the second via layer VIA2. The portion at which the second via layer VIA2 is exposed from the third via layer VIA3 may be a second exposed area EA2. For example, a width of the second exposed area EA2 in the second direction DR2 may be similar to or smaller than the width of the first exposed area EA1 in the second direction DR2.

As such, the first, second, and third via layers VIA1, VIA2, and VIA3 may be stacked while having a stepped shape.

The fourth source metal layer SDL4 may be disposed on the third via layer VIA3. The fourth source metal layer SDL4 may include the first anode electrode AND1 and a first cathode electrode CTD1. The first anode electrode AND1 may be connected to the anode connection electrode ACE while penetrating the third via layer VIA3. The first cathode electrode CTD1 may be connected to a power line while penetrating the third via layer VIA3. In FIG. 7, it is illustrated that the anode AND and a cathode CTD are adjacent to each other in the second direction DR2 to illustrate and describe a shape in which the anode AND and the cathode CTD are connected to a light emitting element ED and a detailed configuration of the light emitting element ED. However, the arrangement of the anode AND and the cathode CTD is not limited thereto. For example, the anode AND and the cathode CTD may be disposed adjacent to each other in the first direction DR1.

A fourth pad electrode PAD4 may be formed with the fourth source metal layer SDL4. The fourth pad electrode PAD4 may be disposed on (e.g., directly on) the third pad electrode PAD3. The fourth pad electrode PAD4 may be formed in the non-display area NDA.

Each of the fourth source metal layer SDL4 and the fourth pad electrode PAD4 may have a single layer or a multi-layer, which is made of one of molybdenum (Mo), aluminum (Al), chromium (Cr), gold (Au), titanium (Ti), nickel (Ni), neodymium (Nd), and copper (Cu), or an alloy thereof.

The anode layer ANDL may be disposed on the fourth source metal layer SDL4. The anode layer ANDL may include a second anode electrode AND2 and a second cathode electrode CTD2. In an embodiment, a thickness of each of the second anode electrode AND2 and the second cathode electrode CTD2 may be smaller than a thickness of each of the first anode electrode AND1 and the first cathode electrode CTD1.

A fifth pad electrode PAD5 may be formed together with the anode layer ANDL. The fifth pad electrode PAD5 may be disposed on (e.g., directly on) the fourth pad electrode PAD4. For example, the fifth pad electrode PAD5 may be in contact with an upper surface and a side surface of the fourth pad electrode PAD4, to cover the fourth pad electrode PAD4. A thickness of the fifth pad electrode PAD5 may be smaller than a thickness of the fourth pad electrode PAD4.

The anode layer ANDL and the fifth pad electrode PAD5 may include a transparent conductive material (TCO) such as Indium Tin Oxide (ITO) or Indium Zinc Oxide (IZO).

The first anode electrode AND1 and the second anode electrode AND2 may form the anode AND (e.g., a first pixel electrode), and the first cathode electrode CTD1 and the second cathode electrode CTD2 may form the cathode CTD (e.g., a second pixel electrode). The first to fifth pad electrodes PAD1 to PAD5 may form the pad part PAD.

The pad part PAD may be disposed on the interlayer insulating layer ILD in the non-display area NDA. The pad part PAD may supply a voltage and/or signal, received from the side surface connection line SCL, to the fan-out line FOL. The second pad electrode PAD2 may be electrically connected to the lead line LDL through the side surface connection line SCL.

The fourth via layer VIA4 may be disposed on the third via layer VIA3 on which the anode AND and the cathode CTD are not formed. The fourth via layer VIA4 may planarize an upper surface of the third via layer VIA3. The fourth via layer VIA4 may include an organic layer including an acrylic resin, an epoxy resin, a phenol resin, a polyamide resin, a polyimide resin, or the like.

In an embodiment, the fourth via layer VIA4 may be disposed in the display area DA. The fourth via layer VIA4 may be spaced apart from the pad part PAD. Also, the fourth via layer VIA4 and the third via layer VIA3 may form a step difference to expose a portion of an upper surface of the third via layer VIA3. The portion at which the third via layer VIA3 is exposed from the fourth via layer VIA4 may be a third exposed area EA3. For example, a width of the third exposed area EA3 in the second direction DR2 may be similar to or smaller than the width of the second exposed area EA2 in the second direction DR2.

The first protective layer PAS1 may be disposed over the fourth via layer VIA4, and cover portions of the anode AND, the cathode CTD, and the pad part PAD. Also, the first protective layer PAS1 may be in contact with the interlayer insulating layer ILD in the interlayer insulating layer exposed area IEA to cover the interlayer insulating layer exposed area IEA of the interlayer insulating layer ILD.

Also, the first protective layer PAS1 may be in contact with the first via layer VIA1, the second via layer VIA2, and the third via layer VIA3. For example, the first protective layer PAS1 may be in contact with the first via layer VIA1 in the first exposed area EA1, be in contact with the second via layer VIA2 in the second exposed area EA2, and be in contact with the third via layer VIA3 in the third exposed area EA3.

The first protective layer PAS1 may include an inorganic layer. For example, the first protective layer PAS1 may include one of a silicon nitride layer, a silicon oxynitride layer, a silicon oxide layer, a titanium oxide layer, and an aluminum oxide layer.

The first protective layer PAS1 may not cover a portion of an upper surface of the anode AND but may exposed the portion of the upper surface of the anode AND. The light emitting element ED may be in contact with the anode AND which is not covered by the first protective layer PAS1 and the cathode CTD.

In an embodiment, the first protective layer PAS1 may cover exposed portions of the first to fourth pad electrodes PAD1 to PAD4. For example, the first protective layer PAS1 may be in contact with the exposed portions of the first to fourth pad electrodes PAD1 to PAD4.

However, the first protective layer PAS1 may not cover a portion of an upper surface of the fifth pad electrode PADS but may expose the portion of the upper surface of the fifth pad electrode PAD5. The side surface connection line SCL may be in contact with (or connected to) the pad part PAD which is not covered by the first protective layer PAS.

In an embodiment, a protective layer including an inorganic material may be further disposed in at least one of between the first via layer VIA1 and the second via layer VIA2, between the second via layer VIA2 and the third via layer VIA3, and between the third via layer VIA3 and the fourth via layer VIA4.

The second protective layer PAS2 may be disposed on the back surface BS of the substrate SUB to planarize the back surface BS of the substrate SUB. The second protective layer PAS may include an inorganic layer. For example, the second protective layer PSA2 may include one of a silicon nitride layer, a silicon oxynitride layer, a silicon oxide layer, a titanium oxide layer, and an aluminum oxide layer.

The back surface electrode BTE may be disposed on a surface (e.g., a back surface) of the second protective layer PAS2. The back surface electrode BTE may supply a voltage or a signal, which is received from the flexible film FPCB, to the side surface connection line SCL through the lead line LCL. The back surface electrode BTE may be electrically connected to the flexible film FPCB through a conductive adhesive member ACF.

The back surface electrode BTE may include a first back surface electrode BTE1 and a second back surface electrode BTE2. The first back surface electrode BTE1 may be disposed on the surface or the back surface of the second protective layer PAS2. The first back surface electrode BTE1 may have a single layer or a multi-layer, which is made of one of molybdenum (Mo), aluminum (Al), chromium (Cr), gold (Au), titanium (Ti), nickel (Ni), neodymium (Nd), and copper (Cu), or an alloy thereof.

The second back surface electrode BTE2 may be disposed on a surface (e.g., a back surface) of the first back surface electrode BTE1. The second back surface electrode BTE2 may include a transparent metal material such as ITO or IZO.

The lead line LDL may be disposed on a surface (e.g., a back surface) of the fifth protective layer PAS5. The lead line LDL and the first back surface electrode BET1 may be formed of a same material in a same layer. The lead line LDL may supply a voltage and/or a signal, received from the back surface electrode BTE to the side surface connection line SCL. For example, as shown in FIG. 6, the lead line LDL may be connected (e.g., physically connected) to the back surface electrode BTE.

The side surface connection line SCL may be disposed at an edge of the back surface BS, the side surface SS, and an edge of the upper surface US of the substrate SUB. An end of the side surface connection line SCL may be connected to the pad part PAD, and another end of the side surface connection line SCL may be connected to the lead line LDL.

In an embodiment, on the upper surface US of the substrate SUB, the side surface connection line SCL may overlap the entire pad part PAD in a plan view. For example, in a plan view, the side surface connection line SCL may cover the entire pad part PAD. In an embodiment, the side surface connection line SCL may overlap the interlayer insulating layer exposed area IEA in a plan view. For example, the side surface connection line SCL may be disposed on the first protective layer PAS1 in the interlayer insulating layer exposed area IEA. On the back surface BS of the substrate SUB, the side surface connection line SCL may cover a portion of the lead line LDL. Accordingly, a risk of electrical disconnection between the pad part PAD and the lead line LDL may be reduced.

The side surface connection line SCL may pass (or cover) side surfaces of the substrate SUB, the buffer layer BF, the first and second gate insulating layers GI1 and GI2, the interlayer insulating layer ILD, and the first protective layer PAS1.

The side surface connection line SCL may have a single layer or a multi-layer, which is made of one of molybdenum (Mo), aluminum (Al), chromium (Cr), gold (Au), titanium (Ti), nickel (Ni), neodymium (Nd), and copper (Cu), or an alloy thereof. For example, the side surface connection line SCL may be made of silver (Ag).

The fifth via layer VIA5 may cover the back surface electrode BTE and a surface (e.g., a back surface) of the lead line LDL. Also, the fifth via layer VIA5 may cover a portion of the side surface connection line SCL. The fifth via layer VIA5 may planarize a lower surface of the substrate SUB. The fifth via layer VIA5 may include an organic layer including an acrylic resin, an epoxy resin, a phenol resin, a polyamide resin, a polyimide resin, or the like.

The third protective layer PAS3 may be disposed on a surface (e.g., a back surface) of the fifth via layer VIA5 to protect the back surface electrode BTE and the lead line LDL. The third protective layer PAS3 may include an inorganic layer. The third protective layer PAS3 may include one of a silicon nitride layer, a silicon oxynitride layer, a silicon oxide layer, a titanium oxide layer, and an aluminum oxide layer.

The flexible film FPCB may be disposed on a surface or a back surface of the third protective layer PAS3. The flexible film FPCB may be attached to the back surface of the third protective layer PAS3, using an adhesive member. A side of the flexible film FPCB may supply a voltage and/or a signal to the pad part PAD through the back surface electrode BTE, the lead line LDL, and the side surface connection line SCL. Another side of the flexible film FPCB may be connected to a source circuit board and the like on the bottom of the substrate SUB. The flexible film FPCB may transmit a signal provided from the source circuit board to the display device 10.

The conductive adhesive member ACF may attach the flexible film FPCB to a back surface of the back surface electrode BTE. For example, the conductive adhesive member ACF may include an anisotropic conductive film. The conductive adhesive member ACF including the anisotropic conductive film may have conductivity in an area in which the back surface electrode BTE and the flexible film FPCB are in contact with each other, and electrically connect the flexible film FPCB to the back surface electrode BTE.

The display device 10 may include the flexible film FPCB disposed on the back surface BS of the substrate SUB, the pad part PAD disposed on the upper surface of the substrate SUB, and the back surface electrode BTE, the lead line LDL, and the side surface connection line SCL, which electrically connect the flexible film FPCB and the pad part PAD to each other, so that the area of the non-display area NDA may be minimized.

In some embodiments, an overcoat layer (not shown) may be further formed over the side surface connection line SCL. For example, the overcoat layer may be an insulating layer, and include an organic insulating material and/or an inorganic insulating material. The overcoat layer may prevent infiltration of pollution into the side surface SS and an edge portion of the display device 10 including the side surface connection line SCL, and protect the side surface connection line SCL.

The light emitting element ED may be disposed on the anode AND and the cathode CTD. In an embodiment, the light emitting element ED may include a flip-chip type micro light emitting diode including a first contact electrode CTE1 and a second contact electrode CTE2, which respectively face the anode AND and the cathode CTD.

The light emitting element ED may include an inorganic material such as GaN. In an embodiment, each of sizes of a width, a length, and a height of the light emitting element ED may be tens to hundreds of μm. For example, each of the width, length, and height of the light emitting element ED may be less than or equal to about 100 μm.

The light emitting element ED may be formed through growth on a semiconductor substrate such as a silicon wafer. The light emitting element ED may be transferred immediately onto the anode AND and the cathode CTD of the substrate SUB from the silicon wafer. In another embodiment, the light emitting element ED may be transferred onto the anode AND and the cathode CTD of the substrate SUB through an electrostatic method using an electrostatic head or a stamp method using, as a transfer substrate, a polymer material having elasticity, such as polydimethylsiloxane (PDMS), silicon or the like.

The light emitting element ED may include a base substrate SSUB, an n-type semiconductor NSEM, an active layer MQW, a p-type semiconductor PSEM, the first contact electrode CTE1, and the second contact electrode CTE2.

The base substrate SSUB may be a sapphire substrate, but the disclosure is not limited thereto.

The n-type semiconductor NSEM may be disposed on a surface of the base substrate SSUB. For example, the n-type semiconductor NSEM may be disposed on a back surface of the base substrate SSUB. The n-type semiconductor NSEM may be made of, for example, GaN doped with an n-type conductive dopant such as Si, Ge, Sn or Se.

The active layer MQW may be disposed on a portion of a surface of the n-type semiconductor NSEM. The active layer MQW may include a material having a single-or multi-quantum well structure. The active layer MQW including the material having the multi-quantum wall structure may have a structure in which multiple well layers and multiple barrier layers are alternately stacked each other. In some embodiments, the well layer may be formed of InGaN, and the barrier layer may be formed of AlGaN. However, the disclosure is not limited thereto. In some embodiments, the active layer MQW may have a structure in which a semiconductor material having high band gap energy and a semiconductor material having low band gap energy are alternately stacked each other, and include Group III to V materials depending on a wavelength band of emitted light.

The p-type semiconductor PSEM may be disposed on a surface (e.g., a back surface) of the active layer MQW. The p-type semiconductor PSEM may be made of GaN doped with a p-type conductive dopant such as Mg, Zn, Ca or Be.

The first contact electrode CTE1 may be disposed on the p-type semiconductor PSEM. The second contact electrode CTE2 may be disposed on another portion of the surface (e.g., a back surface) of the n-type semiconductor NSEM. The another portion of the surface of the n-type semiconductor NSEM, on which the second contact electrode CTE2 is disposed, may be disposed to be spaced apart from the portion of the surface of the n-type semiconductor NSEM, on which the active layer MQW is disposed.

In an embodiment, the first contact electrode CTE1 and the anode AND may be adhered to each other by a conductive adhesive member. The conductive adhesive member may include, for example, an anisotropic conductive film, an anisotropic conductive paste, or the like. In some embodiments, the first contact electrode CTE1 and the anode AND may be adhered to each other through a soldering process. As the first contact electrode CTE1 and the anode AND are adhered to each other, resistance may be decreased.

In an embodiment, the second contact electrode CTE2 and the cathode CTD may be adhered to each other by a conductive adhesive member. The conductive adhesive member may include, for example, an anisotropic conductive film, an anisotropic conductive paste, or the like. In some embodiments, the second contact electrode CTE2 and the cathode CTD may be adhered to each other through a soldering process. As the second contact electrode CTE2 and the cathode CTD are adhered to each other, resistance may be decreased.

The side surface connection line SCL may be formed by applying a conductive material (e.g., including a metal such as silver (Ag) or copper (Cu)) having viscosity (e.g., a predetermined viscosity) onto the side surface SS, the upper surface US, and the back surface BS of the substrate SUB and hardening the applied conductive material. In an embodiment, the side surface connection line SCL may be formed by printing and applying the conductive material onto the side surface SS, the upper surface US, and the back surface BS of the substrate SUB, using the stamp method, and hardening the applied conductive material.

The side surface connection lines SCL may be entirely located on the side surface SS of the substrate SUB, or be located to be spaced apart from each other in the first direction DR1. A method using laser may be used as a method of hardening the conductive material so as to form the side surface connection line SCL. However, a heating area may be limited to a very narrow range due to characteristics of the laser. Therefore, it may take a long time to harden the conductive material so as to form the side surface connection line SCL, using the laser. Accordingly, a method of reducing a time necessary to form the side surface connection line SCL is required.

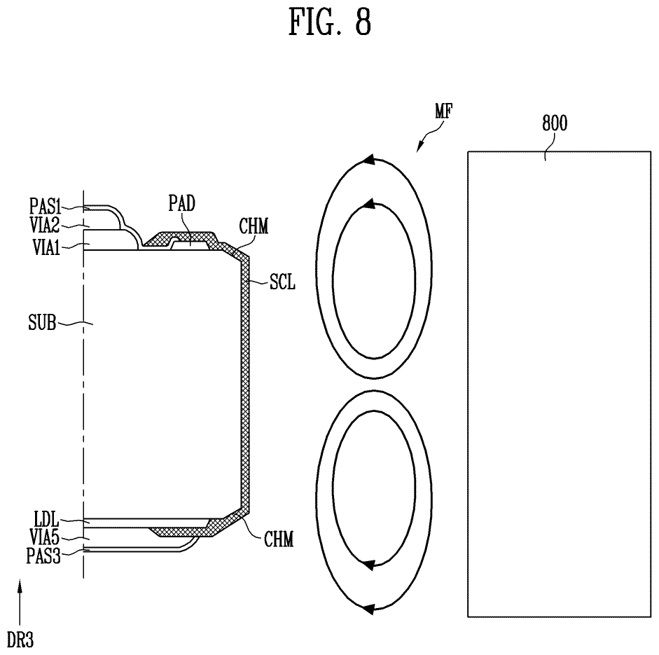

FIG. 8 schematically illustrates an embodiment of a process of forming a side surface connection line SCL of the display device shown in FIG. 5.

Referring to FIG. 8, a method of manufacturing the side surface connection line SCL in accordance with an embodiment of the disclosure may include a step of irradiating an electromagnetic wave onto a surface (e.g., a side surface), using an electromagnetic wave output device 800. The side surface connection line SCL shown in FIG. 8 may be a conductive material for forming the side surface connection line SCL.

The electromagnetic wave output device 800 may generate and output an electromagnetic wave. The electromagnetic wave may be, for example, a microwave. The electromagnetic wave output device 800 may include a magnetron that generates an electromagnetic wave (e.g., a microwave). The electromagnetic wave output from the electromagnetic wave output device 800 may have an electric field and a magnetic field. For convenience of description, a magnetic field MF of the electromagnetic wave is illustrated in FIG. 8.

By the magnetic field MF, an induced current may be formed in the side surface connection line SCL. The direction of the induced current generated in the side surface connection line SCL may be, for example, the third direction DR3.

Heat may be generated in the side surface connection line SCL by the induced current generated in the side surface connection line SCL. The conductive material may be hardened by the heat generated by the induced current. As the conductive material is hardened, the side surface connection line SCL may be formed.

The wavelength of the microwave may be in a range of about 1 mm to about 1 m. The electromagnetic wave output device 800 may irradiate, onto the side surface connection line SCL, an electromagnetic wave having a wavelength in a range of about 1 mm to about 1 m (or a frequency in a range of about 300 MHz (megahertz) to about 30 GHz (gigahertz)).

The wavelength of the electromagnetic wave output from the electromagnetic wave output device 800 may be appropriately selected within the above range according to a kind of the conductive material, a thickness of the side surface connection line SCL, and the like. For example, multiple options for outputting electromagnetic waves having different wavelengths may be provided in the electromagnetic wave output device 800.

In an embodiment in which the thickness of the side surface connection line SCL is about 2 μm, and the conductive material constituting the side surface connection line SCL is silver (Ag), an induced current may flow to a depth of about 2 μm from a surface of the side surface connection line SCL by an electromagnetic wave having a frequency of 2.45 GHz. In an embodiment in which the thickness of the side surface connection line SCL is about 2 μm, and the conductive material constituting the side surface connection line SCL is copper (Cu), an induced current may flow to a depth of about 1.3 μm from a surface of the side surface connection line SCL by the electromagnetic wave having the frequency of 2.45 GHz. However, the disclosure is not limited to the above numerical values, and the above embodiments are merely examples for describing the disclosure.

The frequency and wavelength of the electromagnetic wave output from the electromagnetic wave output device 800 may be appropriately selected based on the material constituting the side surface connection line SCL, and the like within a range in which the frequency and wavelength of the electromagnetic wave are controlled such that an induced current can flow in a range smaller than or equal to the thickness of the side surface connection line SCL.

A time for which the side surface connection line SCL is heated by the electromagnetic wave output device 800 and a temperature at which the side surface connection line SCL is heated by the electromagnetic wave output device 800 may be sufficient as long as the conductive material constituting the side surface connection line SCL can be hardened at the temperature for the time, and the ranges of the time for which the side surface connection line SCL is heated by the electromagnetic wave output device 800 and a temperature at which the side surface connection line SCL is heated by the electromagnetic wave output device 800 are not limited. For example, in the embodiment in which the thickness of the side surface connection line SCL is about 2 μm, and the conductive material constituting the side surface connection line SCL is copper (Cu), the temperature of the side surface connection line SCL may be increased up to about 500° C. by the induced current by irradiating the electromagnetic wave having the wavelength of 2.45 GHz for about one second. However, the disclosure is not limited to the above numerical values, and the above embodiments are merely examples for describing the disclosure.

Power supplied to the electromagnetic wave output device 800 may be sufficient as long as an electromagnetic wave having a predetermined wavelength and a predetermined frequency can be generated by the power, and the range of the power is not limited.

Accordingly, the conductive material applied in a wide area may be effectively heated. Thus, the time necessary to form the side surface connection line SCL may be shortened.

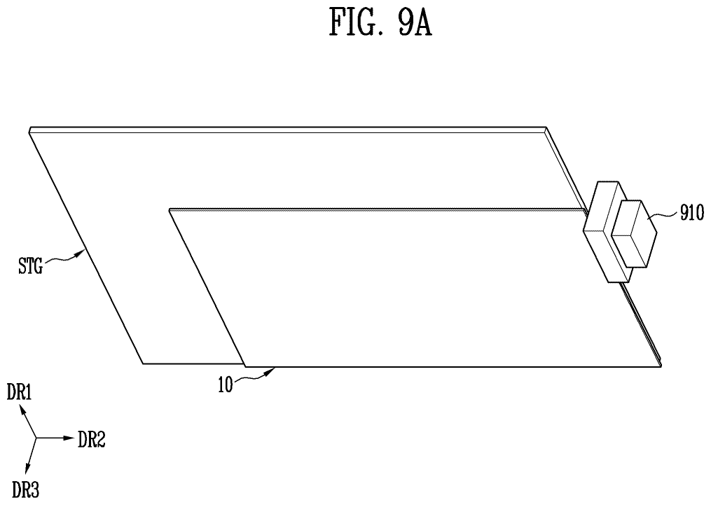

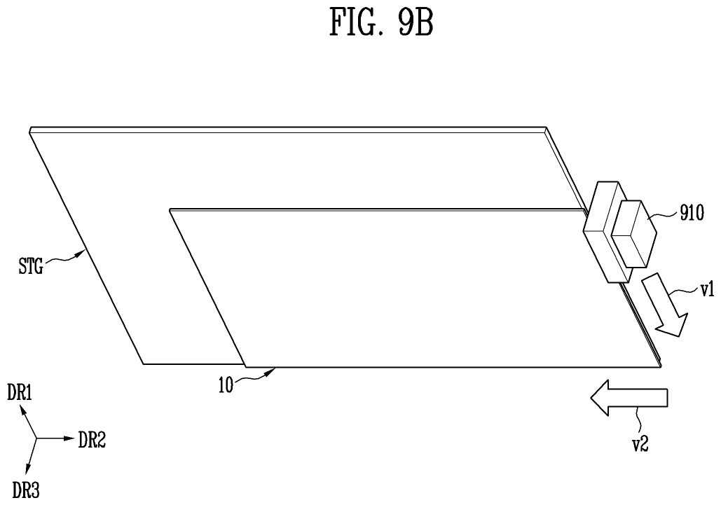

FIGS. 9A and 9B schematically illustrate an embodiment in which an electromagnetic wave output device 800 shown in FIG. 8 includes one electromagnetic wave output unit 910.

The electromagnetic wave output unit 910 may irradiate an electromagnetic wave onto a side surface of the display device 10 in the first direction DR1 or the second direction DR2 of the display device 10.

Although it is illustrated that a size of the electromagnetic wave output unit 910 is smaller than a length of a short side (e.g., a side in a direction parallel to the first direction DR1) of the display device 10, the disclosure is not limited thereto. For example, the size of the electromagnetic wave output unit 910 may be smaller than the length of the short side of the display device 10, but be equal (or substantially equal) to the length of the short side of the display device 10. In some embodiments, the size of the electromagnetic wave output unit 910 may be smaller than a length of a long side (e.g., another side parallel to the second direction DR2) of the display device 10, but be equal (or substantially equal) to the length of the long side of the display device 10. In some embodiments, the size of the electromagnetic wave output unit 910 may be greater than the length of the long side of the display device 10.

The electromagnetic wave output unit 910 may irradiate an electromagnetic wave (e.g., a microwave) onto the side surface of the display device 10 in a state in which the display device 10 is mounted on a stage STG.

Referring to FIG. 9B, the electromagnetic wave output unit 910 may move. The electromagnetic wave output unit 910 may move at a first velocity v1 along a side of the display device 10 (e.g., a short side parallel to the first direction DR1 in the display device 10). The electromagnetic wave output unit 910 may move at a second velocity v2 along another side of the display device 10 (e.g., a long side parallel to the second direction DR2 in the display device 10). The first velocity v1 and the second velocity v2 may be equal (or substantially equal), but the disclosure is not limited thereto. For example, the first velocity v1 may be greater than the second velocity v2, or the second velocity v2 may be greater than the first velocity v1. For example, each of the first velocity v1 and the second velocity v2 may be set to about 100 mm/s, but the disclosure is not limited thereto.

The depth of an area in which an induced current flows may vary according to a moving velocity of the electromagnetic wave output unit 910. For example, in case that the moving velocity of the electromagnetic wave output unit 910 is relatively slow, the depth of an area in which an induced current flows in the side surface connection line SCL (see FIG. 8) may be relatively large. For example, in case that the moving velocity of the electromagnetic wave output unit 910 is relatively fast, the depth of the area in which the induced current flows in the side surface connection line SCL may be relatively small. The moving velocity of the electromagnetic wave output unit 910 may be determined within a range in which the side surface connection line SCL can be hardened. For example, in case that the side surface connection line SCL is formed thin, the side surface connection line SCL may be appropriately hardened even though the moving velocity of the electromagnetic wave output unit 910 is relatively high. Accordingly, a time necessary to form the side surface connection line SCL may be shortened.

In some embodiments, the electromagnetic wave output unit 910 may reciprocate along a side and/or another side of the display device 10.

The electromagnetic wave output unit 910 may irradiate an electromagnetic wave while moving along a side of the display device 10 (e.g., a short side parallel to the first direction DR1 in the display device 10). For example, the electromagnetic wave output unit 910 may irradiate (e.g., continuously irradiate) an electromagnetic wave having a uniform intensity while moving along the short side of the display device 10. For example, the electromagnetic wave output unit 910 may irradiate (e.g., continuously irradiate) an electromagnetic wave having a uniform intensity while moving along a long side of the display device 10. However, the disclosure is not limited thereto, and the electromagnetic wave output unit 910 may intermittently irradiate an electromagnetic wave while moving along a side and/or another side of the display device 10.

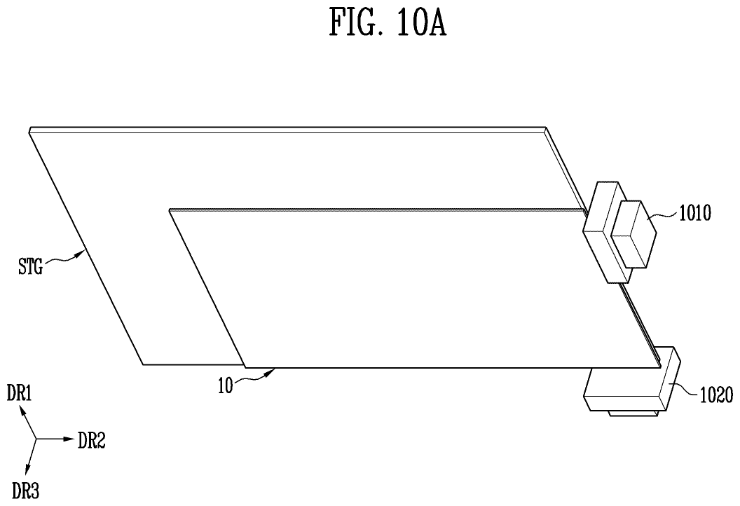

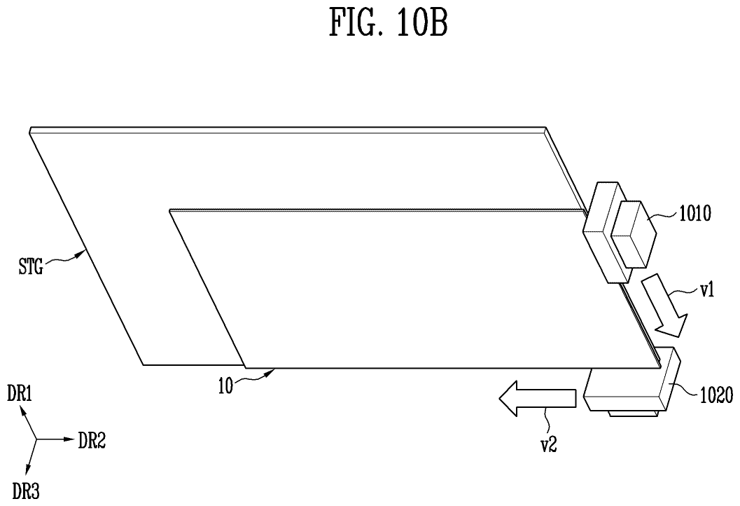

FIGS. 10A and 10B schematically illustrate an embodiment in which the electromagnetic wave output device 800 shown in FIG. 8 includes multiple electromagnetic wave output units 1010 and 1020.

The electromagnetic wave output device 800 (see FIG. 8) in accordance with an embodiment of the disclosure may include multiple electromagnetic wave output units 1010 and 1020. Referring to FIGS. 10A and 10B, the electromagnetic wave output device 800 may include a first electromagnetic wave output unit 1010 and a second electromagnetic wave output unit 1020.

Descriptions of the electromagnetic wave output unit 910 described with reference to FIGS. 9A and 9B may be equally applied to each of the electromagnetic wave output units 1010 and 1020 shown in FIGS. 10A and 10B.

The first electromagnetic wave output unit 1010 may irradiate an electromagnetic wave onto a side surface of the display device 10 in the second direction DR2 of the display device 10.

The second electromagnetic wave output unit 1020 may irradiate an electromagnetic wave onto a side surface of the display device 10 in the first direction DR1 of the display device 10.

Although it is illustrated that a size of the first electromagnetic wave output unit 1010 is smaller than a length of a short side (e.g., a side in a direction parallel to the first direction DR1) of the display device 10, the disclosure is not limited thereto. For example, the size of the first electromagnetic wave output unit 1010 may be smaller than the length of the short side of the display device 10, but be equal (or substantially equal) the length of the short side of the display device 10. In some embodiments, the size of the first electromagnetic wave output unit 1010 may be greater than the length of the short side of the display device 10.

A size of the second electromagnetic wave output unit 1020 may be smaller than a length of a long side (another side in a direction parallel to the second direction DR2) of the display device 10, but be equal (or substantially equal) to the length of the long side of the display device 10. In some embodiments, the size of the second electromagnetic wave output unit 1020 may be greater than the length of the long side of the display device 10.

Each of the first and second electromagnetic wave output units 1010 and 1020 may irradiate an electromagnetic wave (e.g., a microwave) onto the side surface of the display device 10 in a state in which the display device 10 is mounted on a stage STG.

Referring to FIG. 10B, the first and second electromagnetic wave output units 1010 and 1020 may move.

The first electromagnetic wave output unit 1010 may move at a first velocity v1 along a side of the display device 10 (e.g., a short side parallel to the first direction DR1 in the display device 10). The second electromagnetic wave output unit 1020 may move at a second velocity v2 along another side of the display device 10 (e.g., a long side parallel to the second direction DR2 in the display device 10). The first velocity v1 and the second velocity v2 may be equal (or substantially equal), but the disclosure is not limited thereto. For example, the first velocity v1 may be greater than the second velocity v2, or the second velocity v2 may be greater than the first velocity v1.

In some embodiments, the first electromagnetic wave output unit 1010 may reciprocate along a side of the display device 10. In some embodiments, the second electromagnetic wave output unit 1020 may reciprocate along another side of the display device 10.

The first electromagnetic wave output unit 1010 may irradiate an electromagnetic wave while moving along a side of the display device 10 (e.g., a short side parallel to the first direction DR1 in the display device 10). For example, the first electromagnetic wave output unit 1010 may irradiate (e.g., continuously irradiate) an electromagnetic wave having a uniform intensity while moving along the short side of the display device 10. However, the disclosure is not limited thereto, and the first electromagnetic wave output unit 1010 may intermittently irradiate an electromagnetic wave while moving along a side of the display device 10.

The second electromagnetic wave output unit 1020 may irradiate an electromagnetic wave while moving along another side of the display device 10 (e.g., a long side parallel to the second direction DR2 in the display device 10). For example, the second electromagnetic wave output unit 1020 may irradiate (e.g., continuously irradiate) an electromagnetic wave having a uniform intensity while moving along the long side of the display device 10. However, the disclosure is not limited thereto, and the second electromagnetic wave output unit 1020 may intermittently irradiate an electromagnetic wave while moving along another side of the display device 10.

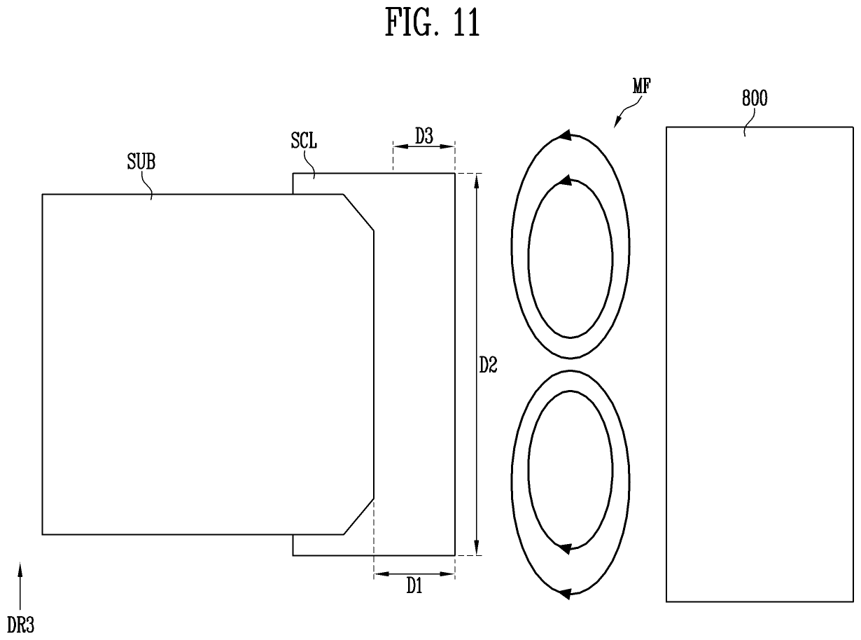

FIG. 11 is a view schematically illustrating the electromagnetic wave output device 800 used in the process shown in FIG. 8 and the side surface connection line SCL of the display device shown in FIG. 5.

Referring to FIG. 11, the electromagnetic wave output device 800 may irradiate an electromagnetic wave, thereby forming a magnetic field MF, and the magnetic field MF may form an induced current in the side surface connection line SCL.

The direction of the induced current generated in the side surface connection line SCL may be, for example, a direction parallel to the third direction DR3.

A depth D3 of an area in which the induced current flows in the side surface connection line SCL may be controlled according to a moving velocity of the electromagnetic wave output device 800 (e.g., the electromagnetic wave output units 910, 1010, and 1020 (see FIGS. 9A to 10B)). For example, in case that the moving velocity of the electromagnetic wave output device 800 is relatively low, the depth D3 of the area in which the induced current flows may be relatively large. For example, in case that the moving velocity of the electromagnetic wave output device 800 is relatively high, the depth D3 of the area in which the induced current flows may be relatively small.

The depth D3 of the area in which the induced current flows may be smaller than a thickness D1 of the side surface connection line SCL. The thickness D1 of the side surface connection line SCL may correspond to a distance from an upper surface of the side surface connection line SCL to the substrate SUB. In case that the depth D3 of the area in which the induced current flows is equal to or greater than the thickness D1 of the side surface connection line SCL, the side surface connection line SCL may be hardened in an area in which the side surface connection line SCL and the substrate SUB are in contact with each other. The adhesion between the side surface connection line SCL and the substrate SUB may be weakened. Therefore, the moving velocity of the electromagnetic wave output device 800 may be controlled within a range in which the depth D3 of the area in which the induced current flows is smaller than the thickness D1 of the side surface connection line SCL. For example, the moving velocity of the electromagnetic wave output device 800 may be set in inverse proportion to the thickness D1 of the side surface connection line SCL. For example, the depth D3 of the area in which the induced current flows may be set within a range in which the depth D3 of the area in which the induced current flows is smaller than the thickness D1 of the side surface connection line SCL and is greater than a half of the thickness D1 of the side surface connection line SCL. However, the disclosure is not limited thereto.

Referring to FIG. 11, it is illustrated that a range of the magnetic field MF (e.g., the magnetic field MF capable of forming the induced current) is greater than a height D2 of the side surface connection line SCL. However, the disclosure is not limited thereto, and the range of the magnetic field MF may be equal to or smaller than the height D2 of the side surface connection line SCL.

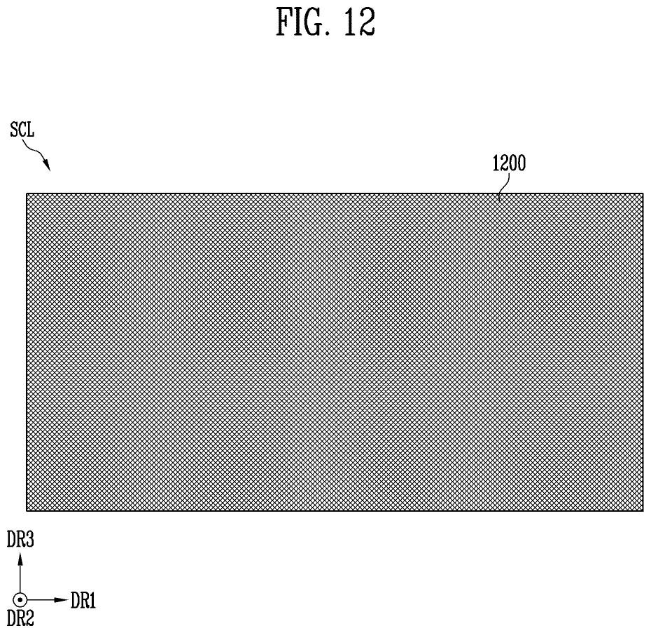

FIG. 12 is a view schematically illustrating a plane heating pattern 1200 provided in the side surface connection line SCL formed through the process shown in FIG. 8.

Referring to FIG. 12, the side surface connection line SCL in accordance with an embodiment of the disclosure may include a plane heating pattern 1200. The side surface connection line SCL in accordance with the embodiment of the disclosure may include the plane heating pattern 1200 formed as the side surface connection line SCL is heated in units of planes by the electromagnetic wave output device 800 (see FIG. 8).

The plane heating pattern 1200 may be viewed on a plane defined by the first direction DR1 and the third direction DR3 and a plane defined by the second direction DR2 and the third direction DR3. The plane heating pattern 1200 may be formed by uniformly heating an area having an area, and be distinguished from a line heating pattern represented as a wave pattern. The above-described line heating pattern may be formed in a process of heating a narrow area, using laser.

In accordance with the embodiments of the disclosure, a wide area of the side surface connection line SCL may be hardened through plane heating. Accordingly, a time necessary to form the side surface connection line SCL may be considerably shortened.

In the display device and the manufacturing method thereof in accordance with the disclosure, a time required to form a side surface connection line may be shortened.

The above description is an example of technical features of the disclosure, and those skilled in the art to which the disclosure pertains will be able to make various modifications and variations. Therefore, the embodiments of the disclosure described above may be implemented separately or in combination with each other.

Therefore, the embodiments disclosed in the disclosure are not intended to limit the technical spirit of the disclosure, but to describe the technical spirit of the disclosure, and the scope of the technical spirit of the disclosure is not limited by these embodiments. The protection scope of the disclosure should be interpreted by the following claims, and it should be interpreted that all technical spirits within the equivalent scope are included in the scope of the disclosure.

What is claimed is:

1. A method of manufacturing a display device, the method comprising:
forming a pad part on an upper surface of a substrate;
forming a lower electrode on a lower surface of the substrate;
connecting the lower electrode and a flexible circuit board to each other;
disposing, on a side surface of the substrate, a conductive material for electrically connecting the pad part and the lower electrode to each other; and
forming a side surface connection line by an electromagnetic wave output device irradiating an electromagnetic wave having a wavelength onto the conductive material on the side surface of the substrate.

2. The method of claim 1, wherein the wavelength of the electromagnetic wave is in a range of about 1 mm to about 1 m.

3. The method of claim 1, wherein the side surface connection line includes one of silver, molybdenum, aluminum, chromium, gold, titanium, nickel, neodymium, and copper, and an alloy thereof.

4. The method of claim 1, wherein
the upper surface and the lower surface are arranged parallel to a plane defined by a first direction and a second direction, which are perpendicular to each other, and
the side surface connection line extends in a third direction perpendicular to the first direction and the second direction, and electrically connects the pad part and the lower electrode to each other.

5. The method of claim 4, wherein an induced current is formed in the third direction by the electromagnetic wave in the side surface connection line.

6. The method of claim 4, wherein
the electromagnetic wave output device includes at least one electromagnetic wave output unit, and
the at least one electromagnetic wave output unit moves in the first direction or the second direction.

7. The method of claim 6, wherein the at least one electromagnetic wave output unit irradiates the electromagnetic wave with a uniform intensity while moving in the first direction or the second direction.

8. The method of claim 6, wherein the at least one electromagnetic wave output unit moves in the first direction along a side of the substrate and moves in the second direction along another side of the substrate.

9. The method of claim 8, wherein a velocity at which the at least one electromagnetic wave output unit moves in the first direction and a velocity at which the at least one electromagnetic wave output unit moves in the second direction are same.

10. The method of claim 6, wherein the electromagnetic wave output device includes:
a first electromagnetic wave output unit moving in the first direction along a side of the substrate; and
a second electromagnetic wave output unit moving in the second direction along another side of the substrate.

11. The method of claim 10, wherein moving velocities of the first electromagnetic wave output unit and the second electromagnetic wave output unit are same.

12. The method of claim 6, wherein a moving velocity of the at least one electromagnetic wave output unit is set according to a thickness of the side surface connection line.

13. The method of claim 12, wherein the moving velocity of the at least one electromagnetic wave output unit is set in inverse proportion to the thickness of the side surface connection line.

14. The method of claim 1, wherein the side surface connection line includes a plane heating pattern.

15. The method of claim 1, wherein the conductive material is printed using a stamp method.

16. The method of claim 1, wherein the electromagnetic wave output device includes a magnetron that generates a microwave.

17. A display device comprising:
a pad part disposed on an upper surface of a substrate;
a lower electrode disposed on a lower surface of the substrate, the lower electrode being electrically connected to a flexible film; and
a side surface connection line that electrically connects the pad part and the lower electrode to each other, the side surface connection line including a conductive material,
wherein the side surface connection line is formed by being heated by an electromagnetic wave having a wavelength.

18. The display device of claim 17, further comprising:
a pixel circuit layer disposed in a display area of the substrate; and
a display element layer disposed on the pixel circuit layer,
wherein the pad part is electrically connected to the pixel circuit layer or the display element layer.

19. The display device of claim 18, wherein the display element layer includes a micro light emitting diode.

20. The display device of claim 17, wherein the side surface connection line includes a plane heating pattern.
